(19) United States
(12) Patent Application Publication
(10) Pub. No.: US 2015/0043178 A1
(43) Pub. Date: Feb. 12, 2015

(54) ELECTRONIC EQUIPMENT AND PLUG-AND-PLAY DEVICE THEREOF

(71) Applicant: Wistron NeWeb Corp., Hsinchu (TW)

(72) Inventors: Chien-Ming PENG, Hsinchu (TW); Chi-Te LIN, Hsinchu (TW)

(73) Assignee: Wistron NeWeb Corp., Hsinchu (TW)

(21) Appl. No.: 14/170,918

(22) Filed: Feb. 3, 2014

(30) Foreign Application Priority Data
Aug. 9, 2013 (TW) 102214968

(51) Int. Cl. H05K 9/00; H05K 7/14

(52) U.S. Cl. CPC H05K 9/0009; H05K 7/1452
USPC 361/752

(57) ABSTRACT

A plug-and-play device is provided. The plug-and-play device includes a device housing, a circuit board, a joint and an electromagnetic shielding frame. The circuit board is disposed in the device housing, including a substrate and a plurality of transmission pins, wherein the transmission pins are formed on the substrate. The transmission pins are connected to the joint. The electromagnetic shielding frame covers the transmission pins.

### CROSS REFERENCE TO RELATED APPLICATIONS

This Application claims priority of Taiwan Patent Application No. 102214968, filed on Aug. 9, 2013, the entirety of which is incorporated by reference herein.

### BACKGROUND OF THE INVENTION

1. Field of the Invention

The present invention relates to a plug-and-play device, and in particular to a plug-and-play device utilized to transmit a wireless signal.

2. Description of the Related Art

The universal serial bus with specification higher than 3.0 is popular, as it transmits data at high speeds. However, the universal serial bus 3.0 generates noise in wireless signal transmissions, particularly with high-frequency wireless signal transmissions. The noise generated by the universal serial bus 3.0 may cause wireless transmission failure in a portable electronic device (for example, a notebook). If a plug-and-play wireless transmission device utilizes universal serial bus 3.0, failure will occur in wireless transmissions, particularly in the high-frequency band.

Conventionally, there is no valid idea about why universal serial bus 3.0 generates noise in wireless signal transmissions.

### BRIEF SUMMARY OF THE INVENTION

A plug-and-play device is provided. The plug-and-play device includes a device housing, a circuit board, a joint, and an electromagnetic shielding frame. The circuit board is disposed in the device housing, including a substrate and a plurality of transmission pins, wherein the transmission pins are formed on the substrate. The transmission pins are connected to the joint. The electromagnetic shielding frame covers the transmission pins.

In the invention, the applicant discovered that the high-frequency transmission of the universal serial bus 3.0 causes the transmission pins to generate a high-frequency electromagnetic wave, which is the reason why universal serial bus 3.0 generates noise. Therefore, shielding the transmission pins with the electromagnetic shielding frame can reduce the noise generated by universal serial bus 3.0. The electromagnetic shielding frame can be disposed on the substrate by surface welding or other means. Utilizing the plug-and-play device of the embodiment of the invention, the electromagnetic shielding frame precisely shields the noise source (transmission pins), and the noise generated by universal serial bus 3.0 is sufficiently reduced.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 shows the plug-and-play device of the first embodiment of the invention;

FIG. 2 shows the detailed structure of the circuit board of the first embodiment of the invention;

FIGS. 3A, 3B, 3C, and 3D show the electromagnetic shielding frame being assembled to the joint frame;

FIG. 4 shows a portion of the plug-and-play device of the second embodiment of the invention;

FIG. 5 shows a portion of the plug-and-play device of the third embodiment of the invention; and

FIG. 6 is the block diagram of the electronic equipment of the embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

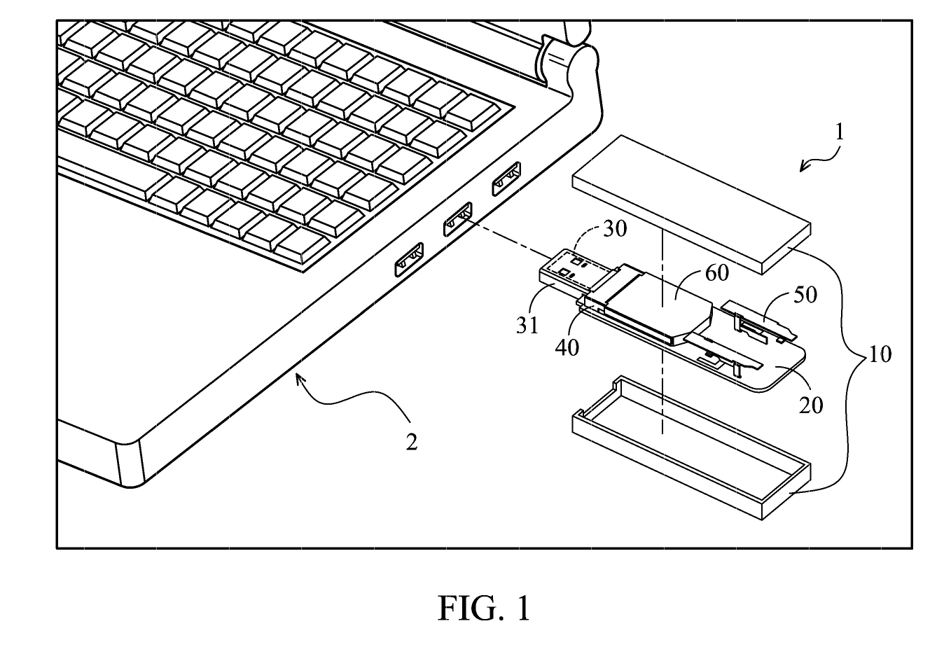

FIG. 1 shows a plug-and-play device 1 of a first embodiment of the invention, which comprises a device housing 10, a circuit board 20, a joint 30, an electromagnetic shielding frame 40, a wireless transmission module 50 and an electromagnetic shielding cover 60.

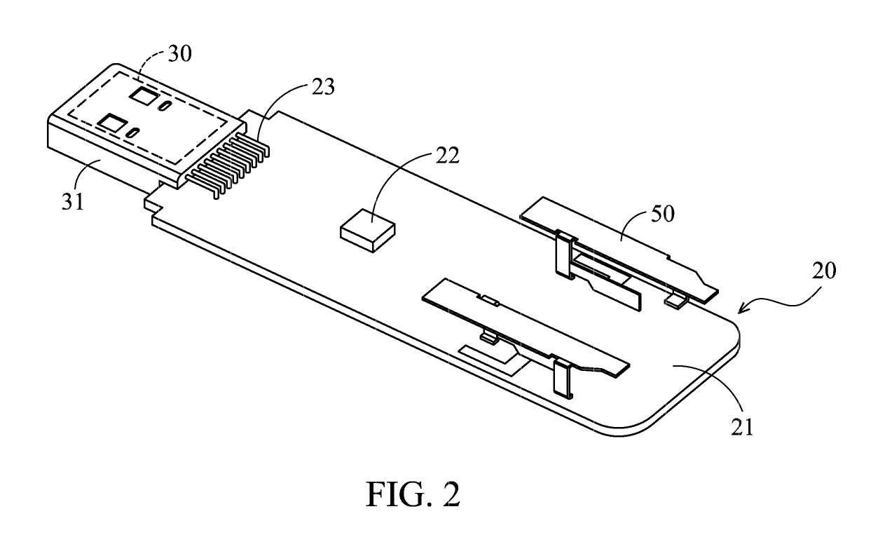

FIG. 2 shows the detailed structure of the circuit board 20 of the first embodiment of the invention. With reference to FIG. 2, the circuit board 20 is disposed in the device housing 10, including a substrate 21, a chip 22 and a plurality of transmission pins 23. The chip 22 and the transmission pins 23 are formed on the substrate 21. The transmission pins 23 are connected to the joint 30. With reference to FIGS. 1 and 2, the electromagnetic shielding frame 40 covers the transmission pins 23. The electromagnetic shielding cover 60 is connected to the electromagnetic shielding frame 40, and the electromagnetic shielding cover 60 covers the chip 22. The wireless transmission module 50 is disposed on the circuit board 20. The wireless transmission module 50 transmits a wireless signal. Generally, the wireless transmission module 50 transmits high-frequency wireless signals and low-frequency wireless signals, or transmits high-frequency wireless signals only (for example, 2.4G and 5G wireless signals).

The joint 30 is a universal serial bus 3.0 joint or a universal serial bus joint with specification higher than 3.0. In conduction research for the invention, the applicant shielded the chip 22 with the electromagnetic shielding cover 60 to insulate the electromagnetic wave generated by the chip 22. However, the applicant found that the noise generated by universal serial bus 3.0 still causes wireless transmission failure even though the chip 22 was shielded by the electromagnetic shielding cover 60. The applicant further discovered that the high-frequency transmission of the universal serial bus 3.0 causes the transmission pins 23 to generate a high-frequency electromagnetic wave, which is the reason why universal serial bus 3.0 generates noise. Therefore, shielding the transmission pins 23 with the electromagnetic shielding frame 40 can reduce the noise generated by universal serial bus 3.0. The electromagnetic shielding frame 40 can be disposed on the substrate by surface welding or other means. Utilizing the plug-and-play device of the embodiment of the invention, the electromagnetic shielding frame precisely shields the noise source (transmission pins), and the noise generated by universal serial bus 3.0 is sufficiently reduced.

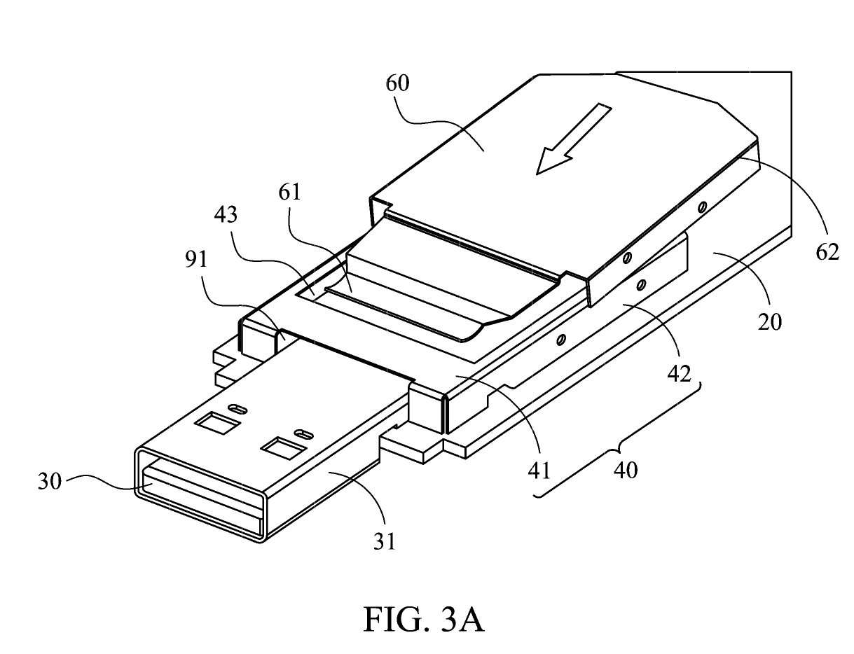

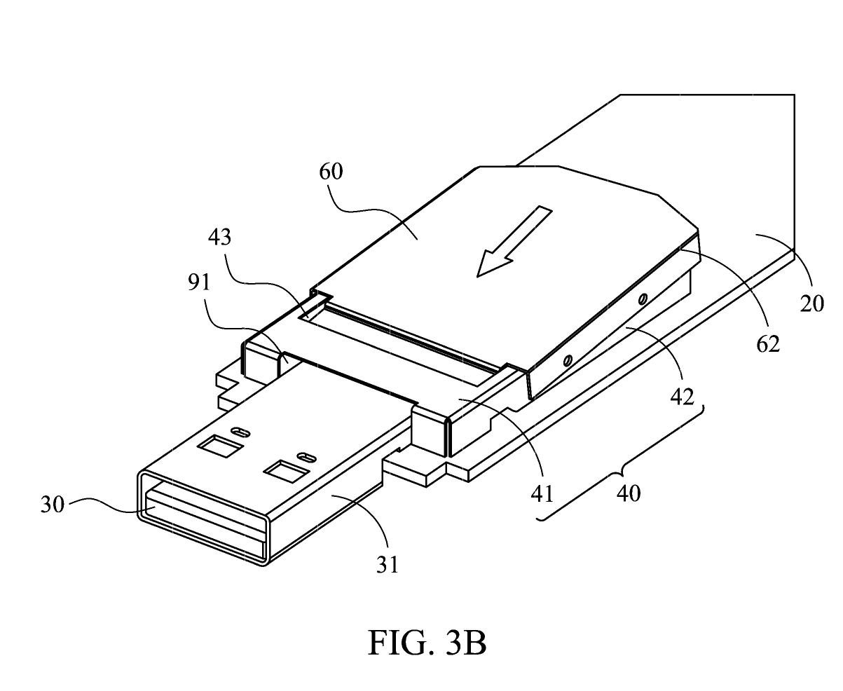

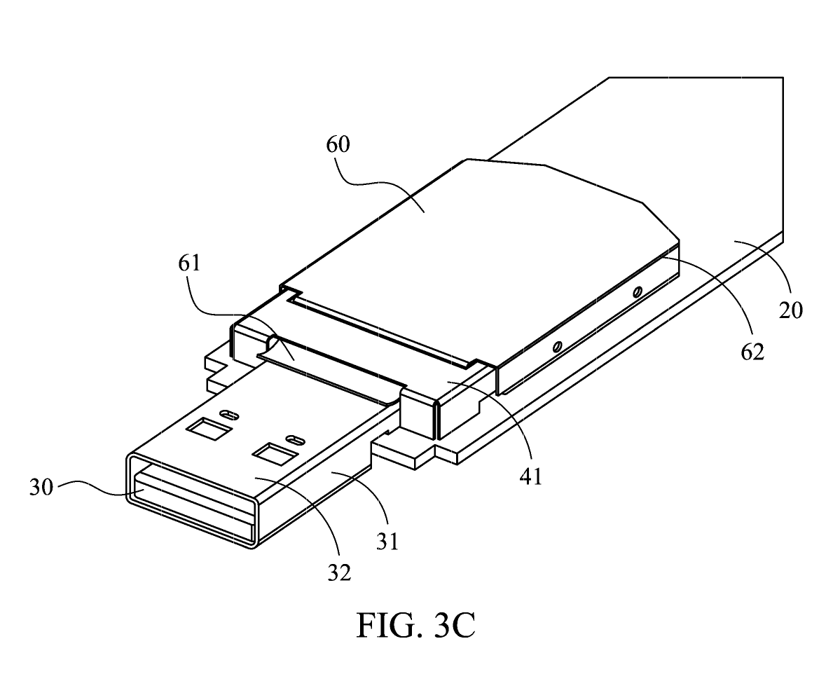

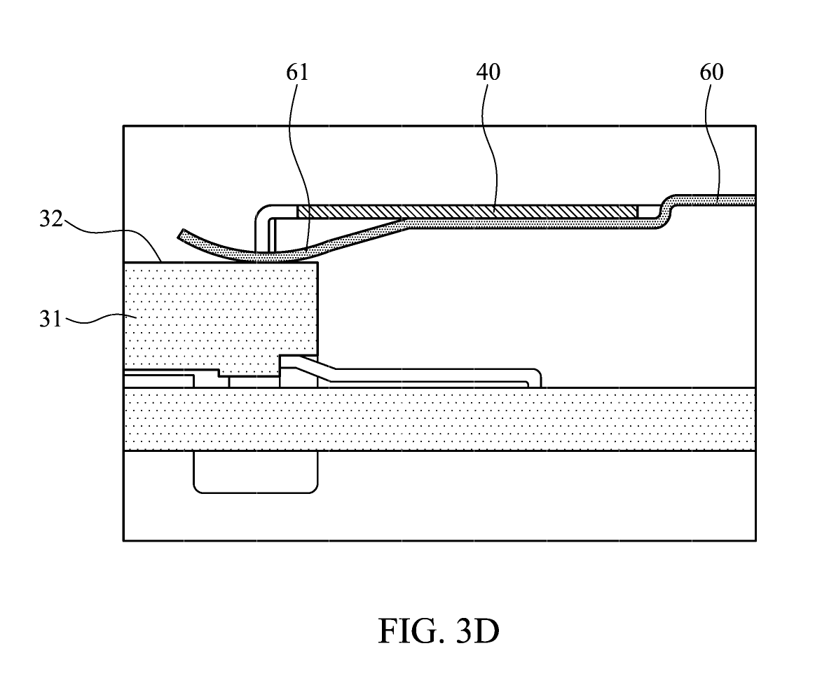

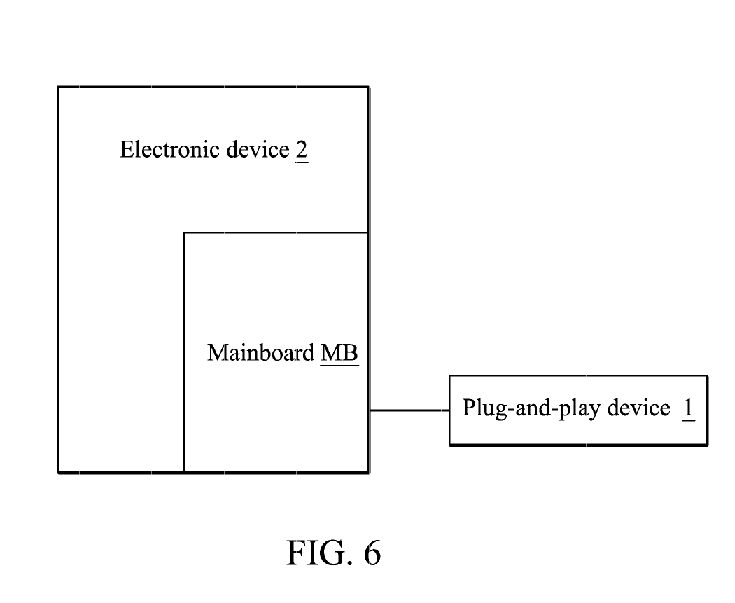

With reference to FIGS. 3A, 3B and 3C, the plug-and-play device 1 further comprises a joint frame 31. The joint frame 31 surrounds the joint 30, wherein a slot 91 is formed between the electromagnetic shielding frame 40 and the joint frame 31. The electromagnetic shielding cover 60 comprises a bending portion 61, the bending portion 61 passes through the slot 91, and the bending portion 61 abuts the joint frame 31. FIGS. 3A, 3B and 3C show the electromagnetic shielding frame 40 being assembled to the joint frame 31. With reference to FIGS. 3C and 3D, FIG. 3D is a sectional view of a portion of the plug-and-play device 1, wherein the bending portion 61 abuts an upper surface 32 of the joint frame 31, the electromagnetic shielding frame 40 and the electromagnetic shielding cover 60 are therefore electrically connected to the joint frame 31. The electromagnetic wave generated by the transmission pins 23 and the chip 22 can be transmitted to the joint frame 31 via the electromagnetic shielding frame 40 and the electromagnetic shielding cover 60, and then be transmitted to a ground portion of a mainboard of electronic equipment 2 (for example, a notebook or a desktop computer, with reference to FIGS. 1 and 6). The ground portion of the mainboard of the electronic equipment has a larger area, and further can reduce the noise generated by universal serial bus.

With reference to FIG. 3A, the electromagnetic shielding frame 40 comprises a covering portion 41 and a supporting portion 42. The covering portion 41 covers the transmission pins 23. The supporting portion 42 is perpendicular to the substrate 21, and the supporting portion 42 surrounds the transmission pins 23 and the chip 22. An opening 43 is defined by the supporting portion 42 and the covering portion 41, and the chip 22 corresponds to the opening 43. The electromagnetic shielding cover 60 comprises an L shaped edge 62, the L shaped edge 62 abuts the supporting portion 42 and is supported thereby, and the electromagnetic shielding cover 60 covers the opening 43 to shield the chip 22. The electromagnetic shielding cover 60 is detachably connected to the electromagnetic shielding frame 40. When the chip 22 is damaged, the electromagnetic shielding cover 60 can be detached, and the chip 22 and its neighboring elements can be repaired or replaced.

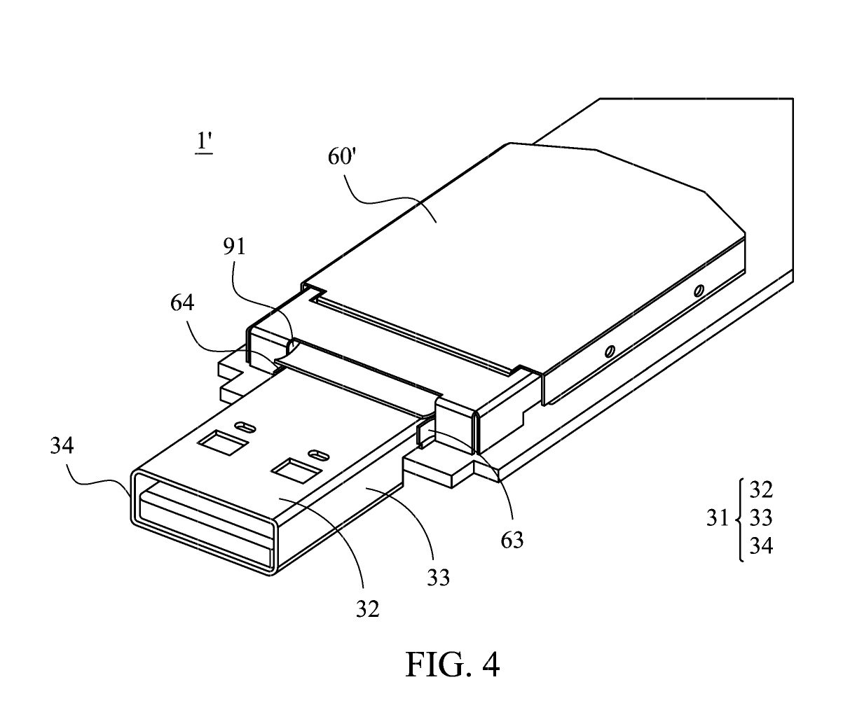

FIG. 4 shows a portion of a plug-and-play device 1′ of a second embodiment of the invention, wherein the electromagnetic shielding cover 60′ comprises a first bending portion 63 and a second bending portion 64. The first bending portion 63 is opposite to the second bending portion 64. The first bending portion 63 and the second bending portion 64 pass through the slot 91, and the first bending portion 63 and the second bending portion 64 abut the joint frame 31. The first bending portion 63 and the second bending portion 64 respectively abut a first lateral surface 33 and a second lateral surface 34 of the joint frame 31, and the first lateral surface 33 is opposite to the second lateral surface 34.

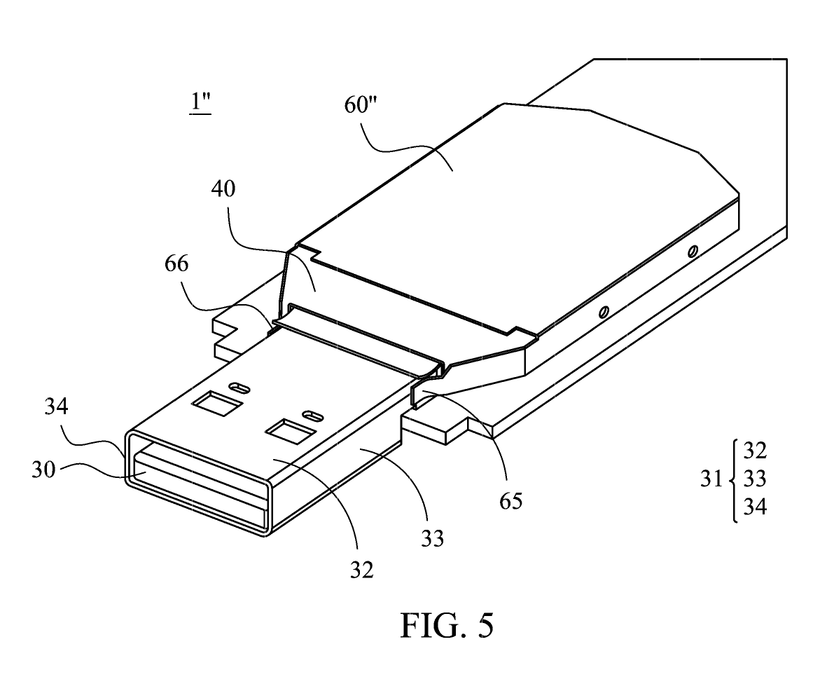

FIG. 5 shows a portion of a plug-and-play device 1″ of a third embodiment of the invention, wherein the electromagnetic shielding cover 60″ comprises a first bending portion 65 and a second bending portion 66. The first bending portion 65 is opposite to the second bending portion 66. The first bending portion 65 and the second bending portion 66 extend over an outer surface of the electromagnetic shielding frame 40 to abut the joint frame 31. The first bending portion 65 and the second bending portion 66 respectively abut a first lateral surface 33 and a second lateral surface 34 of the joint frame 31.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as Co encompass all such modifications and similar arrangements.

What is claimed is:

1. A plug-and-play device, comprising:
a device housing;
a circuit hoard, disposed in the device housing, comprising a substrate and a plurality of transmission pins, wherein the transmission pins are formed on the substrate;
a joint, wherein the transmission pins are connected to the joint; and
an electromagnetic shielding frame, covering the transmission pins.

2. The plug-and-play device as claimed in claim 1, further comprising a wireless transmission module disposed on the circuit board, wherein the wireless transmission module is adapted to transmitting a high-frequency wireless signal.

3. The plug-and-play device as claimed in claim 1, wherein the joint is a universal serial bus 3.0 joint or a universal serial bus joint with specification higher than 3.0.

4. The plug-and-play device as claimed in claim 1, wherein the electromagnetic shielding frame is disposed on the substrate via surface welding.

5. The plug-and-play device as claimed in claim 1, further comprising an electromagnetic shielding cover, wherein the circuit further comprises a chip, the chip is disposed on the substrate, the electromagnetic shielding cover is connected to the electromagnetic shielding frame, and the electromagnetic shielding cover covers the chip.

6. The plug-and-play device as claimed in claim 5, further comprising a joint frame, surrounding the joint, wherein a slot is formed between the electromagnetic shielding frame and the joint frame.

7. The plug-and-play device as claimed in claim 6, wherein the electromagnetic shielding cover comprises a bending portion, the bending portion passes through the slot, and the bending portion abuts the joint frame.

8. The plug-and-play device as claimed in claim 6, wherein the electromagnetic shielding cover comprises a bending portion, the bending portion passes through the slot, and the bending portion abuts an upper surface of the joint frame.

9. The plug-and-play device as claimed in claim 6, wherein the electromagnetic shielding cover comprises a first bending portion and a second bending portion, the first bending portion is opposite to the second bending portion, the first bending portion and the second bending portion pass through the slot, and the first bending portion and the second bending portion abut the joint frame.

10. The plug-and-play device as claimed in claim 9, wherein the first bending portion and the second bending portion respectively abut a first lateral surface and a second lateral surface of the joint frame, and the first lateral surface is opposite to the second lateral surface.

11. The plug-and-play device as claimed in claim 6, wherein the electromagnetic shielding cover comprises a first bending portion and a second bending portion, the first bending portion is opposite to the second bending portion, the first bending portion and the second bending portion extend over an outer surface of the electromagnetic shielding frame to abut the joint frame.

12. The plug-and-play device as claimed in claim 11, wherein the first bending portion and the second bending portion respectively abut a first lateral surface and a second lateral surface of the joint frame, and the first lateral surface is opposite to the second lateral surface.

13. The plug-and-play device as claimed in claim 5, wherein the electromagnetic shielding frame comprises a covering portion and a supporting portion, the covering portion covers the transmission pins, the supporting portion is perpendicular to the substrate, the supporting portion surrounds the transmission pins and the chip, an opening is defined by the supporting portion and the covering portion, and the chip corresponds to the opening.

14. The plug-and-play device as claimed in claim 13, wherein the electromagnetic shielding cover comprises an L shaped edge, the L shaped edge abuts the supporting portion and is supported thereby, and the electromagnetic shielding cover covers the opening to shield the chip.

15. An electronic equipment, comprising:
a mainboard, wherein the mainboard comprises a ground portion; and
a plug-and-play device, comprising:
a device housing;
a circuit board, disposed in the device housing, comprising a substrate and a plurality of transmission pins, wherein the transmission pins are formed on the substrate;
a joint, wherein the transmission pins are connected to the joint;
an electromagnetic shielding frame, covering the transmission pins; and
a joint frame, surrounding the joint, wherein the electromagnetic shielding frame is electrically connected to the ground portion via the joint frame.

16. The electronic equipment as claimed in claim 15, wherein the plug-and-play device further comprises an electromagnetic shielding cover, the circuit further comprises a chip, the chip is disposed on the substrate, the electromagnetic shielding cover is connected to the electromagnetic shielding frame, and the electromagnetic shielding cover covers the chip.

17. The electronic equipment as claimed in claim 16, wherein a slot s formed between the electromagnetic shielding frame and the joint frame, the electromagnetic shielding cover comprises a bending portion, the bending portion passes through the slot, and the bending portion abuts an upper surface of the joint frame.

18. The electronic equipment as claimed in claim 17, wherein the electromagnetic shielding frame comprises a covering portion and a supporting portion, the covering portion covers the transmission pins, the supporting portion is perpendicular to the substrate, the supporting portion surrounds the transmission pins and the chip, an opening is defined by the supporting portion and the covering portion, and the chip is corresponding to the opening.

19. The electronic equipment as claimed in claim 18, wherein the electromagnetic shielding cover comprises an L shaped edge, the L shaped edge abuts the supporting portion and is supported thereby, and the electromagnetic shielding cover covers the opening to shield the chip.
